(19) United States
(12) Patent Application Publication
(10) Pub. No.: US 2026/0231320 A1
(43) Pub. Date: Aug. 6, 2026

(54) ELECTRONIC MODULE AND ELECTRONIC DEVICE

(71) Applicant: CANON KABUSHIKI KAISHA, Tokyo (JP)

(72) Inventors: MASANORI KIKUCHI, Kanagawa (JP); TAKAYUKI TAGUCHI, Kanagawa (JP); SHOJI MATSUMOTO, Kanagawa (JP)

(21) Appl. No.: 19/458,438

(22) Filed: Jan. 23, 2026

(30) Foreign Application Priority Data
Jan. 31, 2025 (JP) 2025-015250

(51) Int. Cl. H05K 1/02; H05K 1/11; H05K 1/181

(52) U.S. Cl. CPC H05K 1/0216; H05K 1/116; H05K 1/181; H05K 2201/09609; H05K 2201/09618; H05K 2201/09636

(57) ABSTRACT

An electronic module is provided that includes a terminal group includes a first signal terminal and a second signal terminal, a first via group includes a first signal via and a second signal via, a second via group includes a third signal via and a fourth signal via, the first signal terminal, the first signal via and the third signal via are electrically connected, the second signal terminal, the second signal via and the fourth signal via are electrically connected, and a distance between a center of the first signal via and a center of the second signal via is greater than a distance between a center of the third signal via and a center of the fourth signal via.

### BACKGROUND

### Field of the Technology

The present disclosure relates to an electronic module and an electronic device.

### Description of the Related Art

Electronic devices such as digital cameras, smartphones, and mobile personal computers (PCs) are becoming more compact, and memory speed, etc. are also becoming faster. A three-dimensional mounting structure formed by stacking a plurality of circuit units as a single structure makes devices more compact. Crosstalk is a problem in speeding up memory speed, etc. In recent years, memory speed has significantly increased, exceeding several GHz, but as signal frequency increases, wavelengths shorten, making issues such as crosstalk more prominent in structures where this was previously not an issue.

For one three-dimensional mounting structure, a method exists of connecting two substrates facing each other by using solder balls using an intermediate connection substrate in which upper and lower connection pads are simply connected by a connection conductor. The intermediate connection substrate can be made using a cost-effective substrate process that simply connects the upper and lower connection pads. In this case, a simple structure is adopted in which the substrates are connected using vias with a same pitch as a pitch of the upper and lower connection pad.

Japanese Patent Laid-Open No. 2014-138015 discusses a printed circuit board in which ground (GND) vias are arranged between differential signal vias forming diagonal columns in a matrix.

Japanese Patent Laid-Open No. 2008-141036 discusses a printed circuit board in which one or more via holes are formed at a position shifted in an approximate center direction in a plan view of an electronic component bonded to a connection pad, which is relative to an approximate center position in a plan view of the connection pad.

Japanese Patent Laid-Open No. 2008-227387 discusses a low-noise semiconductor apparatus in which wiring spacing in a semiconductor package differs from via spacing in a printed circuit board.

When attempting to achieve a three-dimensional mounting structure in a small area, connection pads are densely disposed. Therefore, in a wiring substrate on which connection pads are densely disposed, a signal is routed out after being passed down to an inner layer of the wiring substrate through a via, since it is difficult to route out the signal on a surface layer. As a result, a conductor of a connection substrate and the via in the wiring substrate in the three-dimensional mounting structure are connected over a long distance. When signal frequency increases, the issue of crosstalk becomes more prominent. Alternatively, prioritizing a reduction in crosstalk complicates increasing signal frequency. Thus, an improvement in transmission characteristics in conventional mounting structures could be made.

### SUMMARY

The present disclosure is directed to providing an electronic module having favorable transmission characteristics.

An aspect of the present disclosure provides an electronic module that includes a first substrate including a first via group; an electronic component mounted on the first substrate and including a terminal group; and a second substrate overlapping the first substrate and including a second via group. The terminal group includes a first signal terminal and a second signal terminal, the first via group includes a first signal via and a second signal via, and the second via group includes a third signal via and a fourth signal via. The first signal terminal, the first signal via and the third signal via are electrically connected. The second signal terminal, the second signal via and the fourth signal via are electrically connected. A distance between a center of the first signal via and a center of the second signal via is greater than a distance between a center of the third signal via and a center of the fourth signal via.

Another aspect of the present disclosure provides an electronic module that includes a first substrate including a first via group; an electronic component mounted on the first substrate and including a terminal group; and a second substrate overlapping the first substrate and including a second via group. The terminal group includes a first signal terminal and a first power terminal, the first via group includes a first signal via and a first power via, and the second via group includes a third signal via and a second power via. The first signal terminal, the first signal via and the third signal via are electrically connected. The first power terminal, the first power via and the second power via are electrically connected. A distance between a center of the first signal via and a center of the first power via is smaller than a distance between a center of the third signal via and a center of the second power via.

A further aspect of the present disclosure provides an electronic device that includes a first electronic module and a second electronic module, with the first electronic module and the second electronic module being electrically connected, and with the first electronic module being configured as the above-described electronic module.

Features of the present disclosure will become apparent from the following description of embodiments with reference to the attached drawings. The following description of embodiments is described by way of example.

### BRIEF DESCRIPTION OF THE DRAWINGS

FIG. 1A is a schematic cross-sectional diagram, as viewed from a side, illustrating relationships between signal vias of a wiring substrate and a connection substrate according to a first embodiment.

FIG. 1B is an example of a diagram describing a connection between an electronic component including a terminal group and vias of the wiring substrate.

FIG. 1C is an example of an arrangement diagram, as viewed from above, of signal vias and respective connection pads on a surface connecting the wiring substrate to the connection substrate.

FIG. 2 is a schematic cross-sectional diagram illustrating relationships between signal vias of the wiring substrate, the connection substrate and a mounting substrate according to a second embodiment.

FIG. 3A is a schematic cross-sectional diagram, as viewed from a side, illustrating relationships between signal vias and power vias of the wiring substrate and the connection substrate according to a third embodiment.

FIG. 3B is another example of a diagram describing a connection between the electronic component including a terminal group and vias of the wiring substrate.

FIG. 3C is another example of an arrangement diagram, as viewed from above, of a power via, a signal via and respective connection pads on the surface connecting the wiring substrate to the connection substrate.

FIG. 4 is a schematic cross-sectional diagram, as viewed from a side, illustrating relationships between signal vias and power vias of the wiring substrate, the connection substrate and the mounting substrate according to a fourth embodiment.

FIG. 5A is a schematic cross-sectional diagram, as viewed from a side, illustrating relationships between signal vias of the wiring substrate and the connection substrate according to a fifth embodiment.

FIG. 5B is another example of a diagram describing a connection between the electronic component including a terminal group and vias of the wiring substrate.

FIG. 6 is a schematic cross-sectional diagram illustrating relationships between signal vias of the wiring substrate, the connection substrate and the mounting substrate according to a sixth embodiment.

FIG. 7A is an example of a ball arrangement of connection pads of the connection substrate.

FIG. 7B is another example of a ball arrangement of the connection pads of the connection substrate.

FIG. 8A is an example of an arrangement, as viewed from above, of vias and connection pads according to an experimental example.

FIG. 8B is another example of an arrangement, as viewed from above, of vias and connection pads according to the experimental example.

FIG. 8C is another example of an arrangement, as viewed from above, of vias and connection pads according to the experimental example.

FIG. 8D is another example of an arrangement, as viewed from above, of vias and connection pads according to the experimental example.

FIG. 8E is another example of an arrangement, as viewed from a side, of vias and connection pads according to the experimental example.

FIG. 9 illustrates a result of obtaining a crosstalk amount through simulations using configurations of FIGS. 8A, 8B, 8C and 8D.

FIG. 10A is a schematic cross-sectional diagram, as viewed from a side, illustrating relationships between signal vias of the wiring substrate and the connection substrate of a comparative example.

FIG. 10B is an example of an arrangement diagram, as viewed from above, of signal vias and respective connection pads on the surface connecting the wiring substrate to the connection substrate.

FIG. 11A is a schematic cross-sectional diagram, as viewed from a side, illustrating relationships between a power via and a signal via of the wiring substrate and the connection substrate of the comparative example.

FIG. 11B is an example of an arrangement diagram, as viewed from above, of a signal via, a power via and respective connection pads on the surface connecting the wiring substrate to the connection substrate.

FIG. 12 is an example of a diagram illustrating an application example.

FIG. 13 is another example of a diagram illustrating the application example.

FIG. 14 is another example of a diagram illustrating the application example.

### DESCRIPTION OF THE EMBODIMENTS

Hereinafter, embodiments for implementing a technology of the present disclosure will be described in detail with reference to the drawings.

### First Embodiment

A first embodiment relates to an electronic module.

An electronic module of the present disclosure may include a first substrate including a first via group; an electronic component mounted on the first substrate and including a terminal group; and a second substrate overlapping the first substrate and including a second via group, wherein the terminal group includes a first signal terminal and a second signal terminal, the first via group includes a first signal via and a second signal via, the second via group includes a third signal via and a fourth signal via, the first signal terminal, the first signal via and the third signal via are electrically connected, the second signal terminal, the second signal via and the fourth signal via are electrically connected, and a distance between a center of the first signal via and a center of the second signal via is greater than a distance between a center of the third signal via and a center of the fourth signal via.

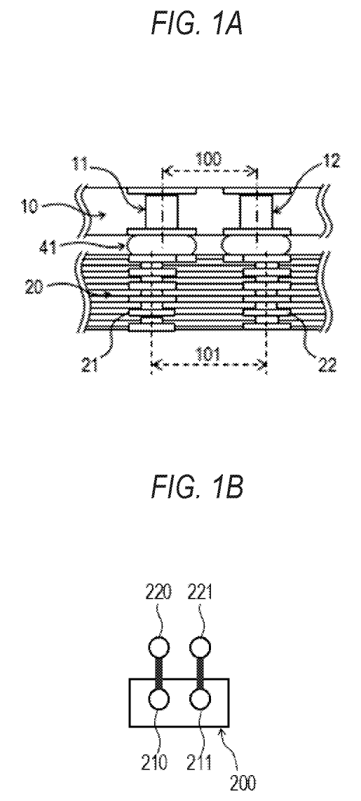

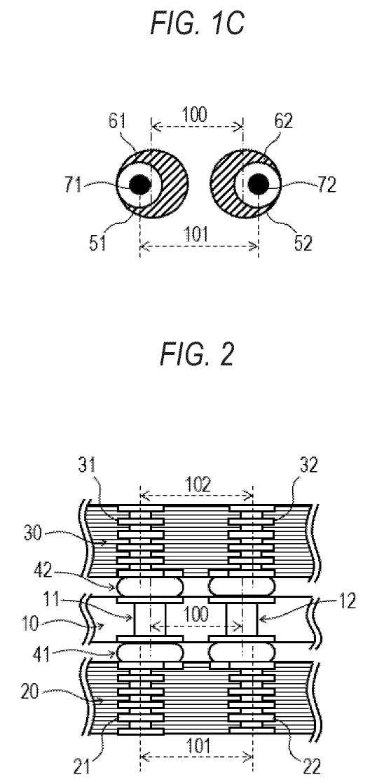

Hereinafter, a configuration of the electronic module of the first embodiment will be described with reference to FIGS. 1A to 1C. FIG. 1A is a schematic cross-sectional diagram illustrating signal via relationships between a first substrate (also referred to as a wiring substrate) and a second substrate (also referred to as a connection substrate) according to the first embodiment.

In FIG. 1A, the electronic module of the present disclosure includes a wiring substrate 20 including a first via group, an electronic component mounted on the wiring substrate 20 and including a terminal group, and a connection substrate 10 overlapping the wiring substrate 20 and including a second via group, the first via group includes a first signal via (also referred to as a signal via 21) and a second signal via (also referred to as a signal via 22), the second via group includes a third signal via (also referred to as a signal via 11) and a fourth signal via (also referred to as a signal via 12). The connection substrate 10 and the wiring substrate 20 are connected using a bonding material 41.

In FIG. 1B, in the electronic module of the present disclosure, the terminal group includes a first signal terminal (also referred to as a signal terminal 211) and a second signal terminal (also referred to as a signal terminal 210), the signal terminal 211, the signal via 21 and the signal via 11 are electrically connected, the signal terminal 210, the signal via 22 and the signal via 12 are electrically connected. As illustrated in FIG. 1B, the signal terminal 211 of an electronic component 200 and a signal via 221 are electrically connected, the signal terminal 210 of the electronic component 200 and a signal via 220 are electrically connected.

FIG. 1C is a diagram describing when signal vias of the wiring substrate 20 are arranged in respective connection pads on a bonding surface of the connection substrate. A first signal via (also referred to as a signal via 61) and a second signal via (also referred to as a signal via 62) in a surface connecting the wiring substrate 20 to the connection substrate 10 are respectively arranged within a signal via connection pad 51 and a signal via connection pad 52. A via pitch 101 of FIG. 1C can also be referred to as a pitch, i.e. distance, between a center of a via plug 71 and a center of a via plug 72 in FIG. 1C.

In the electronic module of the present disclosure, a distance between a center of the signal via 21 and a center of the signal via 22 (the via pitch 101 (the distance between the center of the via plug 71 and the center of the via plug 72 in FIG. 1C)) is greater than a distance between a center of the signal via 11 and a center of the signal via 12 (via pitch 100). In this manner, crosstalk occurring between the signal vias is reduced.

In the electronic module of the present disclosure, a difference between the distance between the center of the signal via 21 and the center of the signal via 22 (the via pitch 101) and the distance between the center of the signal via 11 and the center of the signal via 12 (the via pitch 100) can be 20 μm or more and 80 μm or less. In the electronic module of the present disclosure, a ratio of the difference between the distance between the center of the signal via 11 and the center of the signal via 12 (the via pitch 100) and the distance between the center of the signal via 21 and the center of the signal via 22 (the via pitch 101), to the distance between the center of the signal via 11 and the center of the signal via 12 (the via pitch 100) can be 2.5% or more and 40% or less. In this manner, crosstalk occurring between the signal vias is further reduced.

### Second Embodiment

In a second embodiment, a third substrate (also referred to as a mounting substrate) is further provided to the electronic module of the first embodiment.

With respect to an aspect of the first embodiment, the electronic module of the present disclosure can further include a third substrate including a third via group, wherein the third substrate can be arranged on a side opposite to the first substrate with the second substrate which is sandwiched between the first substrate and the third substrate, the third via group can include a fifth signal via and a sixth signal via, the third signal via and the fifth signal via can be electrically connected, the fourth signal via and the sixth signal via can be electrically connected, and a distance between a center of the fifth signal via and a center of the sixth signal via can be greater than the distance between the center of the third signal via and the center of the fourth signal via.

Hereinafter, a configuration of an electronic module of the second embodiment will be described with reference to FIG. 2. FIG. 2 is a schematic cross-sectional diagram illustrating relationships between signal vias of the wiring substrate 20, a mounting substrate 30 and the connection substrate 10 according to the second embodiment. The electronic module of the present disclosure can include the mounting substrate 30 including a third via group. The mounting substrate 30 can be arranged on a side opposite to the wiring substrate 20 with the connection substrate 10 which is sandwiched between the wiring substrate 20 and the mounting substrate 30. Since the connection substrate 10 is arranged between the wiring substrate 20 and the mounting substrate 30, the connection substrate 10 can also be referred to as the connection substrate.

In the electronic module of the present disclosure, the third via group can include a fifth signal via (also referred to as a signal via 31) and a sixth signal via (also referred to as a signal via 32). The connection substrate 10 and the wiring substrate 20 are connected using the bonding material 41. The connection substrate 10 and the mounting substrate 30 are connected using a bonding material 42. The signal via 11 and the signal via 12 are arranged in the connection substrate 10. The signal via 21 and the signal via 22 are arranged in the wiring substrate 20.

Similar to the first embodiment, the signal terminal 211, the signal via 21 and the signal via 11 are electrically connected, the signal terminal 210, the signal via 22 and the signal via 12 are electrically connected. The third via group further includes the signal via 31 and the signal via 32, the signal via 11 and the signal via 31 are electrically connected, the signal via 12 and the signal via 32 are electrically connected.

In the electronic module of the present disclosure, a distance between a center of the signal via 31 and a center of the signal via 32 (via pitch 102) can be greater than the distance between the center of the signal via 11 and the center of the signal via 12 (via pitch 100), the distance between the center of the signal via 21 and the center of the signal via 22 (the via pitch 101) is greater than the distance between the center of the signal via 11 and the center of the signal via 12 (the via pitch 100). In this manner, crosstalk occurring between signal vias is further reduced.

### Third Embodiment

A third embodiment relates to an electronic module.

An electronic module of the present disclosure may include a first substrate including a first via group; an electronic component mounted on the first substrate and including a terminal group; and a second substrate overlapping the first substrate and including a second via group, wherein the terminal group includes a first signal terminal and a first power terminal, the first via group includes a first signal via and a first power via, the second via group includes a third signal via and a second power via, the first signal terminal, the first signal via and the third signal via are electrically connected, the first power terminal, the first power via and the second power via are electrically connected, and a distance between a center of the first signal via and a center of the first power via is smaller than a distance between a center of the third signal via and a center of the second power via.

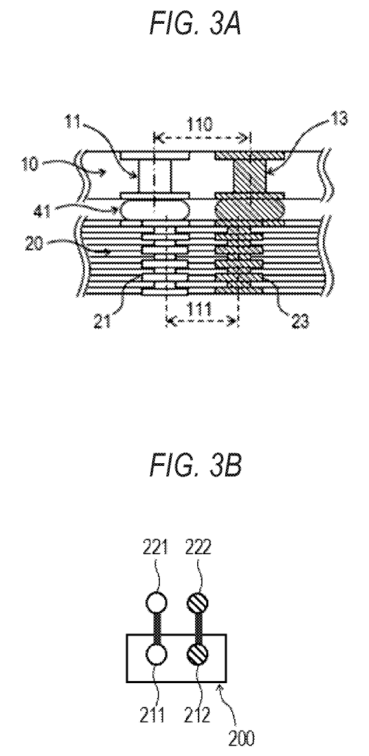

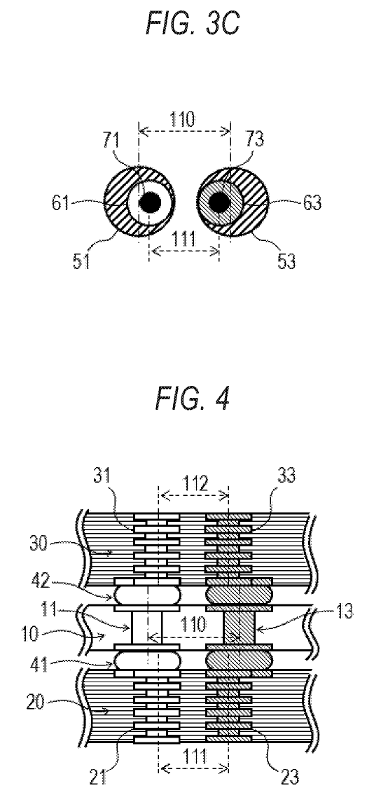

Hereinafter, a configuration of the electronic module of the third embodiment will be described with reference to FIGS. 3A to 3C. FIG. 3A is a schematic cross-sectional diagram illustrating relationships between signal vias and power vias of the wiring substrate 20 and the connection substrate 10 according to the third embodiment. The electronic module of the present disclosure includes the wiring substrate 20 including a first via group, the electronic component mounted on the wiring substrate 20 and including a terminal group, and the connection substrate 10 overlapping the wiring substrate 20 and including a second via group.

In the electronic module of the present disclosure, the first via group includes the signal via 21 and a first power via (also referred to as a power via 23), and the second via group includes the signal via 11 and a second power via (also referred to as a power via 13). The connection substrate 10 and the wiring substrate 20 are connected using the bonding material 41. In the present disclosure, power vias (the power via 23, the power via 13 and a third power via (also referred to as a power via 33)) may be ground vias or power-supply vias. The signal via 11 and the power via 13 are arranged in the connection substrate 10. The signal via 21 and the power via 23 are arranged in the wiring substrate 20.

In the electronic module of the present disclosure, the terminal group includes the signal terminal 211 and a first power terminal (also referred to as a power terminal 212), the signal terminal 211, the signal via 21 and the signal via 11 are electrically connected, the power terminal 212, the power via 23 and the power via 13 are electrically connected.

This is illustrated in FIG. 3B. In FIG. 3B, the signal terminal 211 of the electronic component 200 and the signal via 221 are electrically connected, the power terminal 212 of the electronic component 200 and a power via 222 are electrically connected. In the present disclosure, the power terminal 212 may be a ground terminal or a power-supply terminal.

The electronic component 200 may include a second power terminal. When the power terminal 212 is one of the ground terminal and the power supply terminal, the second power terminal is the other of the ground terminal and the power supply terminal.

FIG. 3C is a diagram describing when a power via and a signal via of the wiring substrate 20 are arranged in respective connection pads on a connection surface of the connection substrate. The signal via 61 and a first power via (also referred to as a power via 63) in the surface connecting the wiring substrate 20 to the connection substrate are respectively arranged within the signal via connection pad 51 and a power via 13 connection pad 53.

In the electronic module of the present disclosure, a distance between the center of the signal via 21 and a center of the power via 23 (via pitch 111) is smaller than a distance between the center of the signal via 11 and a center of the power via 13 (via pitch 110). In this manner, noise reduction of the signal vias can be performed and crosstalk occurring between signal vias is reduced. Here, the via pitch 111 of FIG. 3C can also be referred to as a distance between the center of the via plug 71 and a center of a via plug 73 in FIG. 3C.

In the electronic module of the present disclosure, a difference between the distance between the center of the signal via 11 and the center of the power via 13 (the via pitch 110) and the distance between the center of the signal via 21 and the center of the power via 23 (the via pitch 111) can be 20 μm or more and 80 μm or less. In the electronic module of the present disclosure, a ratio of the difference between the distance between the center of the signal via 11 and the center of the power via 13 (the via pitch 110) and the distance between the center of the signal via 21 and the center of the power via 23 (the via pitch 111), to the distance between the center of the signal via 11 and the center of the power via 13 (the via pitch 110) can be 2.5% or more and 40% or less. In this manner, even more noise reduction of the signal vias can be performed and crosstalk occurring between signal vias is further reduced.

### Fourth Embodiment

In a fourth embodiment, the third substrate (also referred to as the mounting substrate) is further provided to the electronic module of the third embodiment.

With respect to the aspect of the third embodiment, the electronic module of the present disclosure can further include a third substrate including a third via group, wherein the third substrate can be arranged on a side opposite to the first substrate with the second substrate which is sandwiched between the first substrate and the third substrate, the third via group can include a fifth signal via and a third power via, the third signal via and the fifth signal via can be electrically connected, the second power via and the third power via can be electrically connected, and a distance between a center of the fifth signal via and a center of the third power via can be smaller than the distance between the center of the third signal via and the center of the second power via.

Hereinafter, a configuration of an electronic module of the fourth embodiment will be described with reference to FIG. 4. FIG. 4 is a schematic cross-sectional diagram illustrating relationships between signal vias and power vias of the wiring substrate 20, the mounting substrate 30 and the connection substrate 10 according to the fourth embodiment. The electronic module of the present disclosure can include the mounting substrate 30 including a third via group, the mounting substrate 30 can be arranged on the side opposite to the wiring substrate 20 with the connection substrate 10 which is sandwiched between the wiring substrate 20 and the mounting substrate 30.

In the electronic module of the present disclosure, the third via group can include the signal via 31 and the power via 33. The connection substrate 10 and the wiring substrate 20 are connected using the bonding material 41. The connection substrate 10 and the mounting substrate 30 are connected using the bonding material 42. The signal via 11 and the power via 13 are arranged in the connection substrate 10. The signal via 21 and the power via 23 are arranged in the wiring substrate 20. The signal via 31 and the power via 33 are arranged in the mounting substrate 30.

Similar to the third embodiment, the signal terminal 211, the signal via 21 and the signal via 11 are electrically connected, the power terminal 212, the power via 23 and the power via 13 are electrically connected. The signal via 11 and the signal via 31 are electrically connected, the power via 13 and the power via 33 are electrically connected.

In the electronic module of the present disclosure, a distance between the center of the signal via 31 and a center of the power via 33 (via pitch 112) can be smaller than the distance between the center of the signal via 11 and the center of the power via 13 (the via pitch 110). The distance between the center of the signal via 21 and the center of the power via 23 (the via pitch 111) is smaller than the distance between the center of the signal via 11 and the center of the power via 13 (the via pitch 110). In this manner, even more noise reduction of the signal vias can be performed and crosstalk occurring between signal vias is further reduced.

### Fifth Embodiment

In a fifth embodiment, the first power via, the second power via and the first power terminal are further provided to the electronic module of the first embodiment.

In this case, with respect to an aspect of the first embodiment, in the electronic module of the present disclosure, the terminal group can include a first power terminal, the first via group can include a first power via, the second via group can include a second power via, the first power terminal, the first power via and the second power via can be electrically connected, and a distance between the center of the first signal via and a center of the first power via can be smaller than a distance between the center of the third signal via and a center of the second power via.

In the fifth embodiment, the second signal via, the fourth signal via and the second signal terminal are further provided to the electronic module of the third embodiment.

In this case, with respect to an aspect of the third embodiment, in the electronic module of the present disclosure, the terminal group can include a second signal terminal, the first via group can include a second signal via, the second via group can include a fourth signal via, the second signal terminal, the second signal via, and the fourth signal via can be electrically connected, and a distance between the center of the first signal via and a center of the second signal via can be greater than the distance between the center of the first signal via and the center of the first power via.

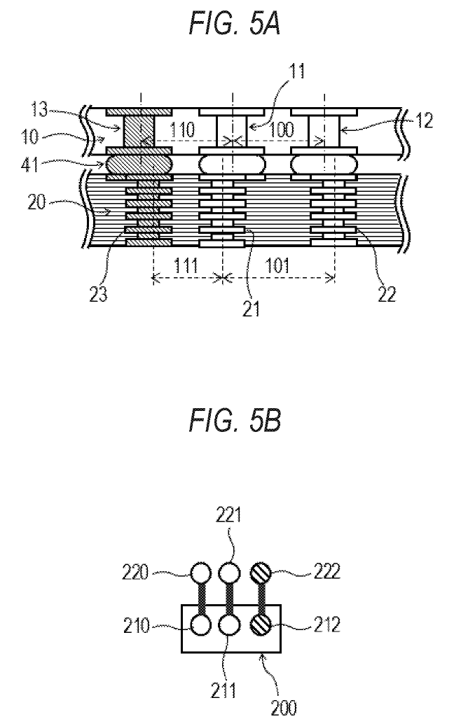

Hereinafter, a configuration of the electronic module of the fifth embodiment will be described with reference to FIGS. 5A and 5B. FIG. 5A is a schematic cross-sectional diagram illustrating relationships between signal vias and power vias of the wiring substrate 20 and the connection substrate 10 according to the fifth embodiment.

The connection substrate 10 and the wiring substrate 20 are connected using the bonding material 41. The signal via 11, the signal via 12, and the power via 13 are arranged in the connection substrate 10. The signal via 21, the signal via 22 and the power via 23 are arranged in the wiring substrate 20.

A terminal group includes the signal terminal 211, the signal terminal 210 and the power terminal 212, the signal terminal 211, the signal via 21 and the signal via 11 are electrically connected, the signal terminal 210, the signal via 22 and the signal via 12 are electrically connected, the power terminal 212, the power via 23 and the power via 13 are electrically connected.

This is illustrated in FIG. 5B. In FIG. 5B, the signal terminal 211 of the electronic component 200 and the signal via 221 are electrically connected, the signal terminal 210 of the electronic component 200 and the signal via 220 are electrically connected, the power terminal 212 of the electronic component 200 and the power via 222 are electrically connected.

In the electronic module of the present disclosure, the distance between the center of the signal via 21 and the center of the power via 23 (the via pitch 111) can be smaller than the distance between the center of the signal via 11 and the center of the power via 13 (the via pitch 110). In the electronic module of the present disclosure, the distance between the center of the signal via 21 and the center of the signal via 22 (the via pitch 101) can be greater than the distance between the center of the signal via 11 and the center of the signal via 12 (the via pitch 100). In this manner, even more noise reduction of the signal vias can be performed and crosstalk occurring between signal vias is further reduced.

In the electronic module of the present disclosure, a difference between the distance between the center of the signal via 21 and the center of the signal via 22 (the via pitch 101) and the distance between the center of the signal via 21 and the center of the power via 23 (the via pitch 111) can be greater than a difference between the distance between the center of the signal via 11 and the center of the signal via 12 (the via pitch 100) and the distance between the center of the signal via 11 and the center of the power via 13 (the via pitch 110). In this manner, even more noise reduction of the signal vias can be performed and crosstalk occurring between signal vias is further reduced.

### Sixth Embodiment

In a sixth embodiment, the fifth signal via, the sixth signal via and the third power via are further provided to the electronic module of the fifth embodiment.

In this case, with respect to an aspect of the fifth embodiment, the electronic module of the present disclosure can further include a third substrate including a third via group, wherein the third substrate can be arranged on a side opposite to the first substrate with the second substrate sandwiched between the first substrate and the third substrate, the third via group can include a fifth signal via, a sixth signal via and a third power via, the third signal via and the fifth signal via can be electrically connected, the fourth signal via and the sixth signal via can be electrically connected, the second power via and the third power via can be electrically connected, and a distance between a center of the fifth signal via and a center of the third power via can be smaller than the distance between the center of the third signal via and the center of the second power via.

In this case, with respect to an aspect of the fifth embodiment, the electronic module of the present disclosure can further include a third substrate including a third via group, wherein the third substrate can be arranged on a side opposite to the first substrate with the second substrate sandwiched between the first substrate and the third substrate, the third via group can include a fifth signal via, a sixth signal via and a third power via, the third signal via and the fifth signal via can be electrically connected, the fourth signal via and the sixth signal via can be electrically connected, the second power via and the third power via can be electrically connected, and a distance between a center of the fifth signal via and a center of the sixth signal via can be greater than a distance between the center of the fifth signal via and a center of the third power via.

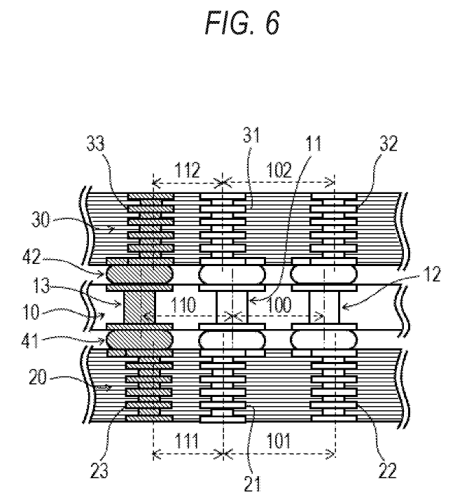

FIG. 6 is a schematic cross-sectional diagram illustrating relationships between signal vias and power vias of the wiring substrate 20, the mounting substrate 30 and the connection substrate 10 according to the sixth embodiment. The connection substrate 10 and the wiring substrate 20 are connected using the bonding material 41. The connection substrate 10 and the mounting substrate 30 are connected using the bonding material 42.

The signal via 11, the signal via 12 and the power via 13 are arranged in the connection substrate 10. The signal via 21, the signal via 22 and the power via 23 are arranged in the wiring substrate 20. The signal via 31, the signal via 32 and the power via 33 are arranged in the mounting substrate 30.

The terminal group includes the signal terminal 211, the signal terminal 210 and the power terminal 212. The signal terminal 211, the signal via 21, the signal via 11 and the signal via 31 are electrically connected, the signal terminal 210, the signal via 22, the signal via 12 and the signal via 32 are electrically connected, the power terminal 212, the power via 23, the power via 13 and the power via 33 are electrically connected. This is similar to what is illustrated in FIG. 5B.

In the electronic module of the present disclosure, the distance between the center of the signal via 31 and the center of the power via 33 (the via pitch 112) can be smaller than the distance between the center of the signal via 11 and the center of the power via 13 (the via pitch 110). In the electronic module of the present disclosure, the distance between the center of the signal via 31 and the center of the signal via 32 (the via pitch 102) can be greater than the distance between the center of the signal via 31 and the center of the power via 33 (the via pitch 112). In this manner, even more noise reduction of the signal vias can be performed and crosstalk occurring between signal vias is further reduced.

In the electronic module of the present disclosure, the distance between the center of the signal via 31 and the center of the power via 33 (the via pitch 112) can be smaller than the distance between the center of the signal via 11 and the center of the power via 13 (the via pitch 110). In the electronic module of the present disclosure, the distance between the center of the signal via 31 and the center of the signal via 32 (the via pitch 102) can be greater than the distance between the center of the signal via 11 and the center of the signal via 12 (the via pitch 100). In this manner, even more noise reduction of the signal vias can be performed and crosstalk occurring between signal vias is further reduced.

In the electronic module of the present disclosure, a difference between the distance between the center of the signal via 31 and the center of the signal via 32 (the via pitch 102) and the distance between the center of the signal via 31 and the center of the power via 33 (the via pitch 112) can be greater than the difference between the distance between the center of the signal via 11 and the center of the signal via 12 (the via pitch 100) and the distance between the center of the signal via 11 and the center of the power via 13 (the via pitch 110). In this manner, even more noise reduction of the signal vias can be performed and crosstalk occurring between signal vias is further reduced.

### Comparative Examples

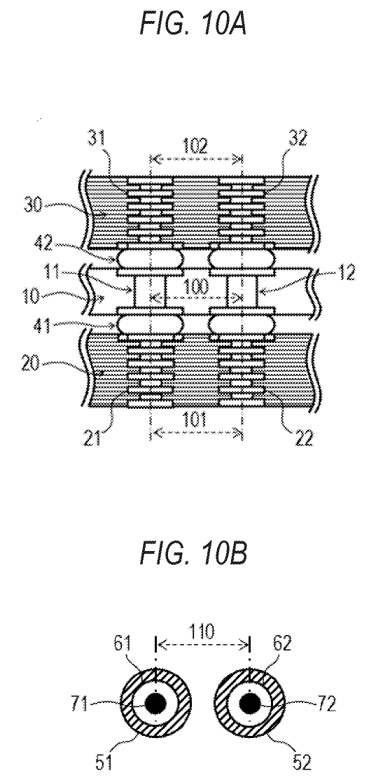

As a comparative example 1, FIG. 10A is a schematic cross-sectional diagram illustrating relationships between signal vias of the wiring substrate 20 (the first substrate), the mounting substrate 30 (the third substrate) and the connection substrate 10 (the second substrate). The connection substrate 10 and the wiring substrate 20 are connected using the bonding material 41. The connection substrate 10 and the mounting substrate 30 are connected using the bonding material 42.

The signal via 11 and the signal via 12 are arranged in the connection substrate 10. The signal via 21 and the signal via 22 are arranged in the wiring substrate 20. The signal via 31 and the signal via 32 are arranged in the mounting substrate 30.

The distance between the signal via 21 and the signal via 22 of the wiring substrate 20 (the via pitch 101) is same as the distance between the signal via 11 and the signal via 12 of the connection substrate 10 (the via pitch 100).

The distance between the signal via 31 and the signal via 32 of the mounting substrate 30 (the via pitch 102) is same as the distance between the signal via 11 and the signal via 12 of the connection substrate 10 (the via pitch 100).

FIG. 10B is a diagram in which signal vias are arranged in respective connection pads on the surface connecting the wiring substrate 20 to the connection substrate. The signal via 61 and the signal via 62 in the surface connecting the wiring substrate 20 to the connection substrate 10 (the second substrate) are respectively arranged in a center of the signal via connection pad 51 and a center of the signal via connection pad 52. The description of the connection between the electronic component including the terminal group and the vias of the wiring substrate is same as that of FIG. 5B.

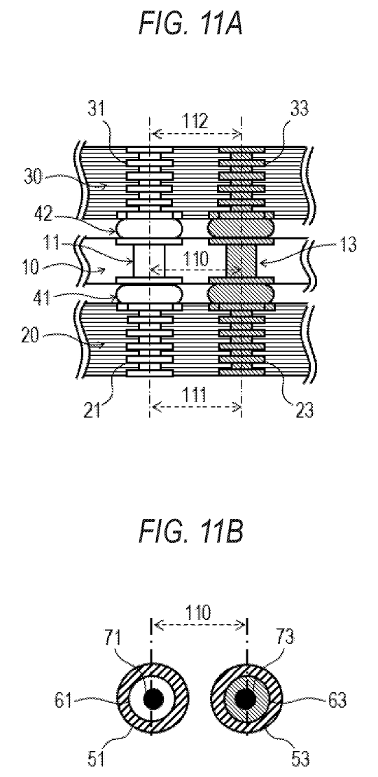

As another comparative example (comparative example 2), FIG. 11A is a schematic cross-sectional diagram illustrating relationships between signal vias and power vias of the wiring substrate 20, the mounting substrate 30 and the connection substrate 10.

The connection substrate 10 and the wiring substrate 20 are connected using the bonding material 41. The connection substrate 10 and the mounting substrate 30 are connected using the bonding material 42. The signal via 11 and the power via 13 are arranged in the connection substrate 10. The signal via 21 and the power via 23 are in the wiring substrate 20. The signal via 31 and the power via 33 are arranged in the mounting substrate 30.

The distance between the signal via 21 and the power via 23 of the wiring substrate 20 (the via pitch 111) is same as the distance between the signal via 11 and the power via 13 of the connection substrate 10 (the via pitch 110). The distance between the signal via 31 and the power via 33 of the mounting substrate 30 (the via pitch 112) is the same as the distance between the signal via 11 and the power via 13 of the connection substrate 10 (the via pitch 110).

### Experimental Examples

In order to verify the effects of the present disclosure, two adjacent signal wires connected through vias to connection pads of the connection substrate disposed in the order of the power via, the signal via, the signal via and a power via were analyzed for S-parameters by using simulation software (CST-Studio).

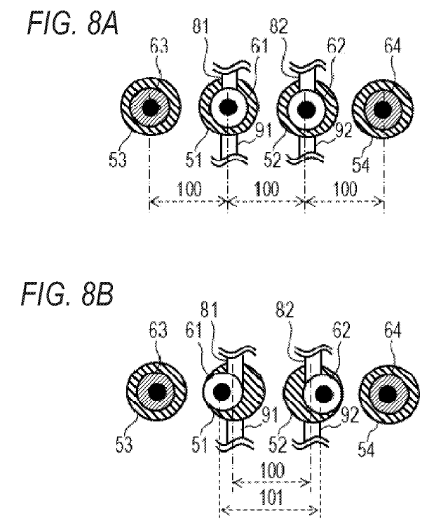

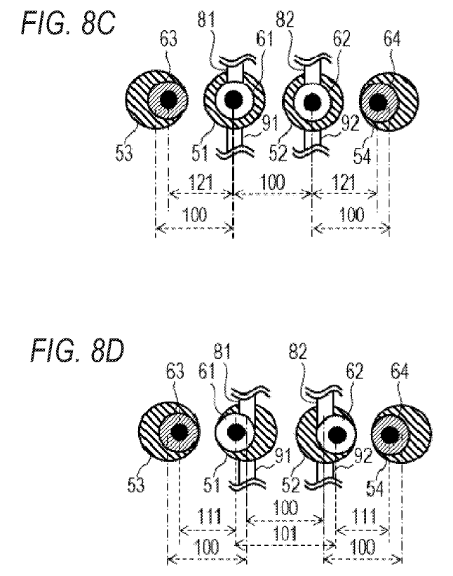

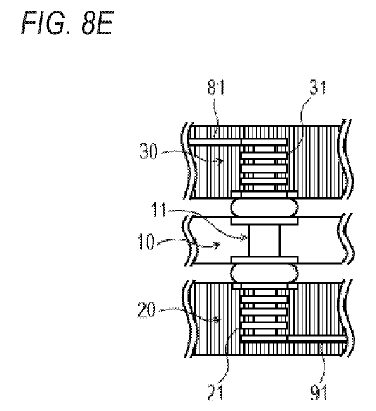

Conditions in which the effects of the present disclosure were confirmed are illustrated in FIGS. 8A to 8D. FIGS. 8A to 8D are conceptual diagrams viewed from above. The signal via 61 is connected to the signal via connection pad 51, and the signal via 62 is connected to the signal via connection pad 52. A first power via (also referred to as a power via 64) is connected to a power via connection pad 54, and the power via 63 is connected to the power via connection pad 53.

A configuration of FIG. 8A corresponds to conditions in which comparative examples 1 and 2 are achieved in a single structure. All distances between the vias of the connection substrate 10, the wiring substrate 20 and the mounting substrate are arranged to be same (for example, the via pitch 100).

In the confirmed conditions, the vias and the connection pads of the connection substrate 10, the wiring substrate 20 and the mounting substrate to be connected are arranged at same positions with a thickness of the connection substrate 10 of 500 μm and the via pitch 100 of uniformly 400 μm. Thicknesses of the wiring substrate 20 and the mounting substrate 30 are both 800 μm, the signal via 21 and the signal via 31 connected to the connection substrate 10 are four-layer stacks, with a via height of 400 μm.

A configuration of FIG. 8B corresponds to conditions assumed for the first embodiment, the via pitch 100 of the connection substrate 10 is same as that in the configuration of FIG. 8A, and corresponds to a condition in which the distance between the adjacent signal via 61 and signal via 62 (the via pitch 101) is set to be greater than the via pitch 100.

A configuration of FIG. 8C corresponds to conditions assumed for the third embodiment. The via pitch 100 of the connection substrate 10 is same as that in the configuration of FIG. 8A, and corresponds to a condition in which a distance between the adjacent signal via 61 and power via 63 (via pitch 121) and a distance between the signal via 62 and the power via 64 (the via pitch 121) is set to be smaller than the via pitch 100 by 40 μm.

A configuration of FIG. 8D corresponds to conditions assumed for the fifth embodiment including both the configuration of FIG. 8B and the configuration of FIG. 8C. The via pitch 100 of the connection substrate 10 is same as in the configuration of FIG. 8A, and corresponds to a condition in which the distance between the adjacent signal via 61 and signal via 62 (the via pitch 101) is set to be greater than the via pitch 100 by 40 μm. The via pitch 100 of the connection substrate 10 corresponds to a condition in which the distance between the adjacent signal via 61 and power via 63 (the via pitch 111) and the distance between the signal via 62 and the power via 64 (the via pitch 111) is set to be smaller than the via pitch 100 by 40 μm.

FIG. 8E is a cross-sectional diagram as viewed from a left side of FIGS. 8A to 8D. Electrodes were laid out with wires of 10 mm by using a wire 81 and a wire 91, and crosstalk characteristics were confirmed. In FIG. 8E, a wire 82 and a wire 92 are arranged behind the wire 81 and the wire 91.

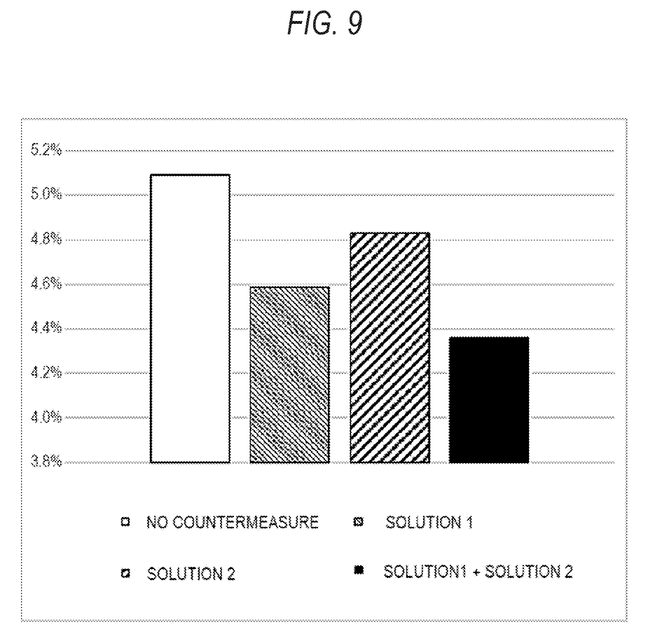

FIG. 9 illustrates a result of confirming the effectiveness of the present countermeasures through simulations.

A horizontal axis represents conditions illustrated in configurations of FIGS. 8A to 8D, and a vertical axis represents a crosstalk amount between two signals. When a value on the vertical axis is lower, crosstalk is lower with indicating a positive characteristic.

In contrast to the case of "no countermeasure" indicated by the configuration of FIG. 8A, improvement can be observed for "solution 1" indicated by the configuration of FIG. 8B and "solution 2" indicated by the configuration of FIG. 8C. Further improvement is achieved by combining solutions 1 and 2 indicated by the configuration of FIG. 8D ("solution 1 + solution 2").

### Variations

FIG. 11B is a diagram in which a signal via and a power via are arranged in respective connection pads on the surface connecting the wiring substrate to the connection substrate. The signal via 61 and the power via 63 in the surface connecting the wiring substrate 20 to the connection substrate are respectively arranged in the center of the signal via connection pad 51 and a center of the power via connection pad 53.

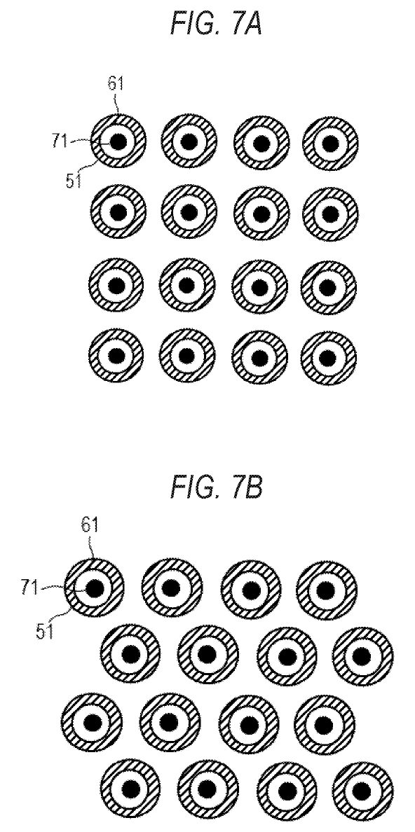

FIG. 7A is an example of a ball arrangement of connection pads of the connection substrate. When a number of signals is high, the connection pads are densely arranged in a grid. Therefore, since the signals cannot be routed using signal wires, etc. except at end portions, vias are used to route out the signals by using inner wiring layers.

Since more advanced processes can be used for the wiring substrate than the connection substrate, pitch restrictions are relatively relaxed. FIG. 7B is an example of a ball arrangement of the connection pads of the connection substrate as an alternative arrangement.

### Other

In the electronic module of the present disclosure, the via pitch, e.g., the distance between the center of the first signal via 21 and the center of the second signal via 22, of the wiring substrate 20 can be 800 μm or less. An example of the via pitch of the connection pads is 400 μm. The via pitch of the connection pads cannot be easily reduced since the electronic module has a risk of mounting defects during mass production when reducing the via pitch too much.

In the electronic module of the present disclosure, the via pitch, e.g., the distance between the center of the third signal via 11 and the center of the fourth signal via 12, of the connection substrate 10 can be 200 μm or more and 800 μm or less. An example of the via pitch of the connection substrate 10 (the second substrate) is 400 μm. Since the connection substrate is made as a through-hole substrate which has no wiring and is low-cost, design rules cannot be made as strict as for the wiring substrate and the via pitch cannot easily be reduced.

### Application Example

An application example relates to an electronic device. The electronic device of the present disclosure includes a first electronic module and a second electronic module, in which the first electronic module and the second electronic module are electrically connected. The first electronic module is an electronic module of the present disclosure.

In the electronic device of the present disclosure, the second electronic module can include an imaging element.

In the following description, the electronic device of the present disclosure can be applied to, for example, a digital camera 600, the first electronic module of the present disclosure can be applied to, for example, a three-dimensional mounting structure 500, and the second electronic module of the present disclosure can be applied to, for example, an image sensor 700.

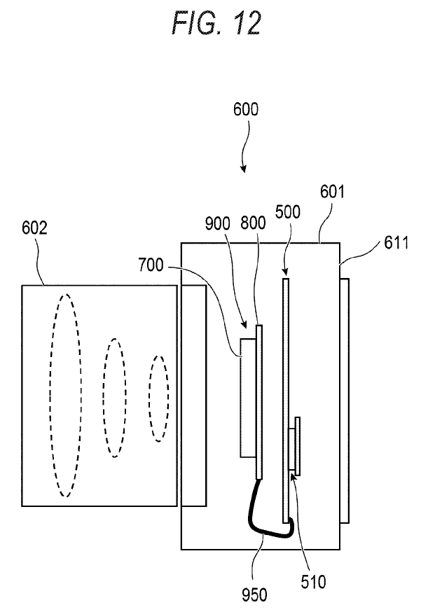

An example of the electronic device using a three-dimensional mounting structure according to the application example will be described with reference to FIG. 12. FIG. 12 is a schematic diagram illustrating the interchangeable lens digital camera 600, which is an example of the electronic device, using the three-dimensional mounting structure 500 according to the application example.

In the application example, the interchangeable lens digital camera 600 will be described, but the digital camera 600 may be of an integrated-lens type in which a lens is built into a camera body 601. The electronic device in which the three-dimensional mounting structure 500 according to the application example is used is not limited to the digital camera 600, which is an imaging device, but may be any type of device.

For example, the electronic device including the electronic module may be an information device such as a smartphone or a personal computer, or may be a communication device such as a modem or router. Alternatively, the module may be used in an office device or a printing device such as a printer, a copier, or a scanner; a medical device such as an X-ray imaging device or an endoscopes; an industrial device such as a robot or semiconductor manufacturing device; or a transportation device such as a vehicle, an airplane or a ship.

A function of an electronic component in the electronic module of the present disclosure varies and is not limited to a memory (storage element), but may be any of a processor (arithmetic element), a sensor (detection element) and a display (display element). The electronic component may also be a communication element, a control element, a power-supply element, etc.

As illustrated in FIG. 12, the digital camera 600 is, for example, an interchangeable lens digital camera such as a digital single-lens reflex camera or a digital mirrorless camera, and includes the camera body 601 and a lens unit 602 including lenses. The lens unit 602 is detachably attached to the camera body 601.

The camera body 601 includes a housing 611, the three-dimensional mounting structure 500 and a sensor module 900. The three-dimensional mounting structure 500 and the sensor module 900 are each an electronic module and are arranged inside the housing 611. The three-dimensional mounting structure 500 and the sensor module 900 are electrically connected to each other via a flexible wire 950. The flexible wire 950 is, for example, a flexible cable or a flexible wiring board.

The sensor module 900 includes the image sensor 700, which is an imaging element, and a printed circuit board 800. The image sensor 700 is mounted on the printed circuit board 800. The image sensor 700 is, for example, a complementary metal oxide semiconductor (CMOS) image sensor or a charge coupled device (CCD) image sensor. The image sensor 700 has a function of converting light incident via the lens unit 602 into an electrical signal.

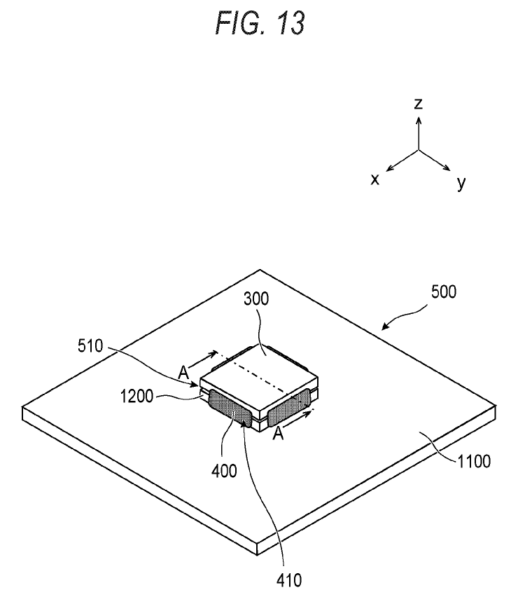

Next, a configuration of the three-dimensional mounting structure 500 according to the application example will be described with reference to FIG. 13. FIG. 13 is a perspective view illustrating the three-dimensional mounting structure 500 according to the application example. In the following explanation, among planar directions of a printed circuit board 1100 to be described below, a direction parallel to one longitudinal direction of a reinforcing resin portion 410 to be described below is referred to as an x-axis direction, and a direction orthogonal to the x-axis direction in a planar direction is referred to as a y-axis direction, as illustrated in FIG. 13. A direction orthogonal to the x-axis direction and the y-axis direction is referred to as a z-axis direction. The x-axis direction, the y-axis direction and the z-axis direction do not necessarily need to be orthogonal to each other, and may intersect one another.

As illustrated in FIG. 13, the three-dimensional mounting structure 500 includes a mounting structure 510, the printed circuit board 1100 and the reinforcing resin portion 410. The three-dimensional mounting structure 500 includes a semiconductor apparatus 1200. The reinforcing resin portion 410 is made of a resin 400. The mounting structure 510 is mounted on one main surface of the printed circuit board 1100, serving as a mounting surface thereof. The printed circuit board 1100 is, for example, a rigid substrate, and is a printed wiring board on which a component is mounted.

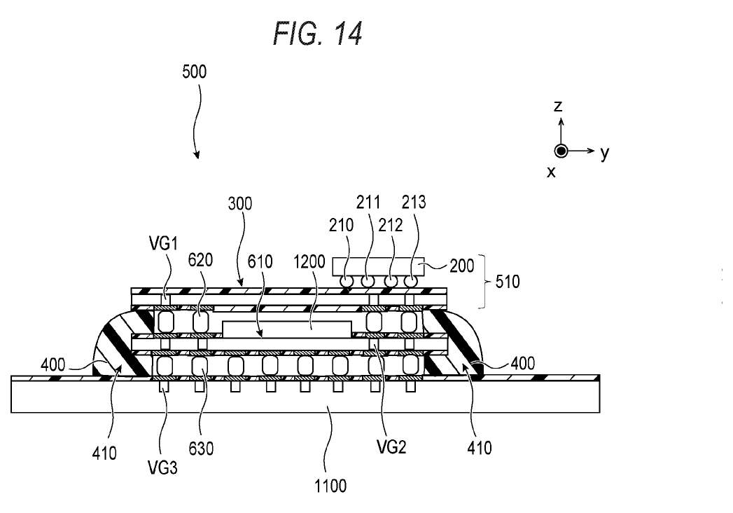

As illustrated in FIG. 14, the three-dimensional mounting structure 500 further includes a printed wiring board 610. The mounting structure 510 includes, for example, the electronic component 200, which is a semiconductor apparatus such as a memory, and a printed circuit board 300 on which the electronic component 200 is mounted. The mounting structure 510 is a structure in which the printed circuit board 300 is mounted on the printed wiring board 610 via a solder joint 620.

The printed wiring board 610 is mounted on the printed circuit board 1100 via a solder joint 630. The electronic component 200 mounted on the printed circuit board 300 includes a terminal group including the signal terminals 210 and 211 and power terminals 212 and 213. One of the power terminal 212 and the power terminal 213 is a power-supply terminal, and the other of the power terminal 212 and the power terminal 213 is a ground terminal.

The semiconductor apparatus 1200 is, for example, a digital signal processor, acquires an electrical signal from the image sensor 700, performs image processing on the acquired electrical signal, and has a function of generating image data.

Therefore, the mounting structure 510 can be referred to as a processing module. The electric signal, the image data, etc. are stored in the electronic component 200 being a memory. In an example of FIG. 14, the semiconductor apparatus 1200 is mounted on the printed wiring board 610, but may be mounted on the printed circuit board 1100.

When the semiconductor apparatus 1200 is mounted on the printed circuit board 1100, the semiconductor apparatus 1200 may be mounted on a main surface on which the mounting structure 510 is mounted (the one main surface), or may be mounted on a main surface opposite to the main surface on which the mounting structure 510 is mounted (the other main surface), among the two main surfaces of the printed circuit board 1100.

The printed circuit board 300 is, for example, a rigid substrate, and is the printed wiring board 610 on which the electronic component 200 is mounted. The reinforcing resin portion 410 is made of the resin 400, and fixes the printed circuit board 1100 and the mounting structure 510.

The reinforcing resin portion 410 may be omitted. The printed circuit board 300 corresponds to the wiring substrate 20 of each embodiment, the printed wiring board 610 corresponds to the connection substrate 10 of each embodiment, and the printed circuit board 1100 corresponds to the mounting substrate 30 of each embodiment. The printed circuit board 300 includes a first via group VG1, the printed wiring board 610 includes a second via group VG2, and the printed circuit board 1100 includes a third via group VG3. A connection relationship between the terminal group, the first via group VG1 and the second via group VG2 may be designed according to the above-described embodiments.

According to the present disclosure, an advantageous technology is provided for achieving favorable transmission characteristics.

According to the above configurations, a low noise electronic module is provided. For example, transmission between a processing engine and a memory of a digital camera, etc. can be sped up, and performance of the electronic device such as the digital camera can be improved.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-015250, filed January 31, 2025, which is hereby incorporated by reference herein in its entirety.

What is claimed is:

1. An electronic module comprising:
a first substrate comprising a first via group;
an electronic component mounted on the first substrate and comprising a terminal group; and
a second substrate overlapping the first substrate and comprising a second via group, wherein
the terminal group comprises a first signal terminal and a second signal terminal,
the first via group comprises a first signal via and a second signal via,
the second via group comprises a third signal via and a fourth signal via,
the first signal terminal, the first signal via and the third signal via are electrically connected,
the second signal terminal, the second signal via and the fourth signal via are electrically connected, and
a distance between a center of the first signal via and a center of the second signal via is greater than a distance between a center of the third signal via and a center of the fourth signal via.

2. The electronic module according to claim 1, wherein
a difference between the distance between the center of the first signal via and the center of the second signal via and the distance between the center of the third signal via and the center of the fourth signal via is 20 μm or more and 80 μm or less.

3. The electronic module according to claim 1, wherein
a ratio of a difference between the distance between the center of the third signal via and the center of the fourth signal via and the distance between the center of the first signal via and the center of the second signal via, to the distance between the center of the third signal via and the center of the fourth signal via is 2.5% or more and 40% or less.

4. The electronic module according to claim 1, further comprising:
a third substrate comprising a third via group, wherein
the third substrate is arranged on a side opposite to the first substrate, with the second substrate sandwiched between the first substrate and the third substrate,
the third via group comprises a fifth signal via and a sixth signal via,
the third signal via and the fifth signal via are electrically connected,
the fourth signal via and the sixth signal via are electrically connected, and
a distance between a center of the fifth signal via and a center of the sixth signal via is greater than the distance between the center of the third signal via and the center of the fourth signal via.

5. The electronic module according to claim 1, wherein
the terminal group further comprises a first power terminal,
the first via group further comprises a first power via,
the second via group further comprises a second power via,
the first power terminal, the first power via and the second power via are electrically connected, and
a distance between the center of the first signal via and a center of the first power via is smaller than a distance between the center of the third signal via and a center of the second power via, and/or
the distance between the center of the first signal via and the center of the first power via is smaller than a distance between the center of the second signal via and the center of the first power via, and/or
a difference between the distance between the center of the first signal via and the center of the second signal via and the distance between the center of the first signal via and the center of the first power via is greater than a difference between the distance between the center of the third signal via and the center of the fourth signal via and the distance between the center of the third signal via and the center of the second power via.

6. The electronic module according to claim 5, further comprising:
a third substrate comprising a third via group, wherein
the third substrate is arranged on a side opposite to the first substrate, with the second substrate sandwiched between the first substrate and the third substrate,
the third via group comprises a fifth signal via, a sixth signal via and a third power via,
the third signal via and the fifth signal via are electrically connected,
the fourth signal via and the sixth signal via are electrically connected,
the second power via and the third power via are electrically connected, and
a distance between a center of the fifth signal via and a center of the third power via is smaller than the distance between the center of the third signal via and the center of the second power via, and/or
a distance between a center of the fifth signal via and a center of the sixth signal via is greater than a distance between the center of the fifth signal via and a center of the third power via, and/or
a difference between a distance between the center of the fifth signal via and a center of the sixth signal via and the distance between the center of the fifth signal via and the center of the third power via is greater than a difference between the distance between the center of the third signal via and the center of the fourth signal via and the distance between the center of the third signal via and the center of the second power via.

7. An electronic module comprising:
a first substrate comprising a first via group;
an electronic component mounted on the first substrate and comprising a terminal group; and
a second substrate overlapping the first substrate and comprising a second via group, wherein
the terminal group comprises a first signal terminal and a first power terminal,
the first via group comprises a first signal via and a first power via,
the second via group comprises a third signal via and a second power via,
the first signal terminal, the first signal via and the third signal via are electrically connected,
the first power terminal, the first power via and the second power via are electrically connected, and
a distance between a center of the first signal via and a center of the first power via is smaller than a distance between a center of the third signal via and a center of the second power via.

8. The electronic module according to claim 7, wherein
a difference between the distance between the center of the third signal via and the center of the second power via and the distance between the center of the first signal via and the center of the first power via is 20 μm or more and 80 μm or less.

9. The electronic module according to claim 7, wherein
a ratio of a difference between the distance between the center of the third signal via and the center of the second power via and the distance between the center of the first signal via and the center of the first power via, to the distance between the center of the third signal via and the center of the second power via is 2.5% or more and 40% or less.

10. The electronic module according to claim 7, further comprising:
a third substrate comprising a third via group, wherein
the third substrate is arranged on a side opposite to the first substrate, with the second substrate sandwiched between the first substrate and the third substrate,
the third via group comprises a fifth signal via and a third power via,
the third signal via and the fifth signal via are electrically connected,
the second power via and the third power via are electrically connected, and
a distance between a center of the fifth signal via and a center of the third power via is smaller than the distance between the center of the third signal via and the center of the second power via.

11. The electronic module according to claim 7, wherein
the terminal group further comprises a second signal terminal,
the first via group further comprises a second signal via,
the second via group further comprises a fourth signal via,
the second signal terminal, the second signal via and the fourth signal via are electrically connected, and
a distance between the center of the first signal via and a center of the second signal via is greater than the distance between the center of the first signal via and the center of the first power via, and/or
the distance between the center of the first signal via and the center of the second signal via is greater than a distance between the center of the third signal via and a center of the fourth signal via, and/or
a difference between the distance between the center of the first signal via and the center of the second signal via and the distance between the center of the first signal via and the center of the first power via is greater than a difference between the distance between the center of the third signal via and the center of the fourth signal via and the distance between the center of the third signal via and the center of the second power via.

12. The electronic module according to claim 11, further comprising:
a third substrate comprising a third via group, wherein
the third substrate is arranged on a side opposite to the first substrate, with the second substrate sandwiched between the first substrate and the third substrate,
the third via group comprises a fifth signal via, a sixth signal via and a third power via,
the third signal via and the fifth signal via are electrically connected,
the fourth signal via and the sixth signal via are electrically connected,
the second power via and the third power via are electrically connected, and
a distance between a center of the fifth signal via and a center of the sixth signal via is greater than a distance between the center of the fifth signal via and a center of the third power via, and/or
the distance between the center of the fifth signal via and the center of the sixth signal via is greater than the distance between the center of the third signal via and the center of the fourth signal via, and/or
a difference between the distance between the center of the fifth signal via and the center of the sixth signal via and the distance between the center of the fifth signal via and the center of the third power via is greater than a difference between the distance between the center of the third signal via and the center of the fourth signal via and the distance between the center of the third signal via and the center of the second power via.

13. The electronic module according to claim 1, wherein
the distance between the center of the third signal via and the center of the fourth signal via of the second substrate is 200 μm or more and 800 μm or less.

14. The electronic module according to claim 7, wherein
the distance between the center of the third signal via and the center of the second power via of the second substrate is 200 μm or more and 800 μm or less.

15. The electronic module according to claim 1, wherein
the distance between the center the first signal via and the first signal via of the first substrate is 800 μm or less.

16. The electronic module according to claim 7, wherein
the distance between the center the first signal via and the first power via of the first substrate is 800 μm or less.

17. An electronic device comprising:
a first electronic module; and
a second electronic module, wherein
the first electronic module and the second electronic module are electrically connected, and
the first electronic module is the electronic module according to claim 1.

18. The electronic device according to claim 17, wherein
the second electronic module comprises an imaging element.

19. An electronic device comprising:
a first electronic module; and
a second electronic module, wherein
the first electronic module and the second electronic module are electrically connected, and
the first electronic module is the electronic module according to claim 7.

20. The electronic device according to claim 19, wherein
the second electronic module comprises an imaging element.
